(19) United States
(12) Patent Application Publication
(10) Pub. No.: US 2026/0060061 A1
(43) Pub. Date: Feb. 26, 2026

(54) INTEGRATED CIRCUIT INCLUDING STANDARD CELL

(71) Applicant: SAMSUNG ELECTRONICS CO., LTD., Suwon-si (KR)

(72) Inventors: Kwangmuk Lee, Suwon-si (KR); Saehan Park, Suwon-si (KR); Jung Han Lee, Suwon-si (KR); Byung-Sung Kim, Suwon-si (KR); Kwanyoung Chun, Suwon-si (KR)

(21) Appl. No.: 19/072,593

(22) Filed: Mar. 6, 2025

(30) Foreign Application Priority Data
Aug. 26, 2024 (KR) 10-2024-0114561

(51) Int. Cl. H01L 23/528; H10D 80/20

(52) U.S. Cl. CPC H01L 23/5286; H10D 80/251

(57) ABSTRACT

An example integrated circuit includes a first layer that extends in a first direction and a second layer that is disposed below the first layer. The second layer extends in a second direction perpendicular to the first direction, is electrically connected to the first layer, and corresponds to a first signal pin of a first standard cell among a plurality of standard cells. A position of the first layer in the second direction is substantially the same as a position of a first cell boundary, among a plurality of cell boundaries of the plurality of standard cells in the first direction, in the second direction.

### CROSS-REFERENCE TO RELATED APPLICATION

This application claims priority to and the benefit of Korean Patent Application No. 10-2024-0114561 filed at the Korean Intellectual Property Office on Aug. 26, 2024, the entire contents of which are incorporated herein by reference.

### BACKGROUND

An integrated circuit that processes a digital signal may be designed using standard cells. A functional circuit may be formed by disposing and routing the standard cells so that the integrated circuit implements a desired function.

As demand for high performance, high speed, and/or multifunctionality of the integrated circuit increases, a degree of integration of the integrated circuit increases. Various studies on a layout structure of the standard cell are being actively conducted to minimize routing congestion and optimize an area of the integrated circuit according to a trend of high integration of the integrated circuit.

### SUMMARY

The present disclosure relates to an integrated circuit including a standard cell that minimizes routing congestion and optimizes an area of the integrated circuit, and an integrated circuit including a standard cell that minimizes a turnaround time (TAT).

In general, according to some aspects, an integrated circuit includes: a first layer that extends in a first direction; and a second layer that is below the first layer, wherein the second layer extends in a second direction perpendicular to the first direction, the second layer is electrically connected to the first layer, and the second layer corresponds to a first signal pin of a first standard cell among a plurality of standard cells, and wherein the first layer overlaps a first cell boundary among a plurality of cell boundaries of the plurality of standard cells in the first direction.

In general, according to some aspects, an integrated circuit includes: a first standard cell that includes a gate line and a first contact layer, the gate line corresponding to a first signal pin and extending in a first direction, the first contact layer corresponding to a second signal pin and extending in the first direction; and a first layer that is electrically connected to the gate line or the first contact layer, wherein the first layer extends in a second direction perpendicular to the first direction at a layer above the gate line and the first contact layer.

In general, according to some aspects, an integrated circuit includes: a first layer that extends in a first direction, wherein the first layer is configured to supply a power source voltage; a second layer that is spaced apart from the first layer along a second direction perpendicular to the first direction, wherein the second layer extends in the first direction, and the second layer is at the same layer as the first layer; a first standard cell that includes a third layer corresponding to a first signal pin, wherein the first signal pin is configured to transmit a signal, the third layer is below the first layer, the third layer is electrically connected to the second layer, and the first standard cell is electrically connected to the first layer; and a second standard cell that includes a fourth layer corresponding to a second signal pin, wherein the second signal pin is configured to receive the signal, the fourth layer is at the same layer as the third layer, and the fourth layer is electrically connected to the second layer.

### BRIEF DESCRIPTION OF THE DRAWINGS

FIG. 1 is a flowchart for describing a design and manufacturing method of an example of an integrated circuit.

FIG. 2 is a cross-sectional view of an example of the integrated circuit.

FIG. 3 is a layout diagram of an example of a standard cell.

FIG. 4 is a layout diagram of an example of an integrated circuit.

FIG. 5 is a layout diagram of an example of an integrated circuit.

FIG. 6 is a cross-sectional view of an example of the integrated circuit along a line A-A′ of FIG. 5.

FIG. 7 is a cross-sectional view of an example of the integrated circuit along a line B-B′ of FIG. 5.

FIG. 8 is a cross-sectional view of an example of the integrated circuit along a line C-C′ of FIG. 5.

FIG. 9 is a layout diagram of an example of an integrated circuit.

FIG. 10 is a layout diagram of an example of the integrated circuit.

FIG. 11 is a cross-sectional view of an example of an integrated circuit.

FIG. 12 is a layout diagram of an example of the integrated circuit.

FIG. 13 is a view schematically showing a design system of an example of the integrated circuit.

FIG. 14 is a view showing an example of a semiconductor device.

### DETAILED DESCRIPTION

Hereinafter, implementations of the present disclosure will be described in detail with reference to the accompanying drawings. The same reference numerals are used for the same constituent elements on the drawings, and duplicate descriptions for the same constituent elements are omitted.

It should be understood that implementations described in the present specification are intended to implement various features of the present disclosure. The implementations are just examples, and are not intended to be restricted. For example, dimensions of components are not limited to a disclosed range or value, and may vary depending on a process condition and/or a property of a desired device. In the following description, formation of a first structure above or on a second structure may include implementations in which the first structure and the second structure are formed in direct contact, and may also include implementations in which additional structures are formed between the first structure and the second structure so that the first structure and the second structure do not directly contact each other. For simplicity and clarity, various structures may be arbitrarily drawn in different scales.

A spatially relative term such as “below”, “under”, “lower”, “above”, “upper”, or “higher” may be used for ease of description to describe a relationship of one element or structure to another element or structure illustrated in the drawings.

In order to clearly describe the present disclosure, parts or portions that are irrelevant to the description are omitted, and identical or similar constituent elements throughout the specification are denoted by the same reference numerals. In a flowchart described with reference to the drawings, an order of operations may be changed, several operations may be merged, a certain operation may be divided, and a specific operation may not be performed.

A singular form may be intended to include a plural form as well, unless an explicit expression such as “one” or “single” is used. Terms including ordinal numbers such as “first” and “second” may be used only to describe various constituent elements, but the constituent elements are not limited by the terms. The terms may be used for a purpose of distinguishing one constituent element from another constituent element.

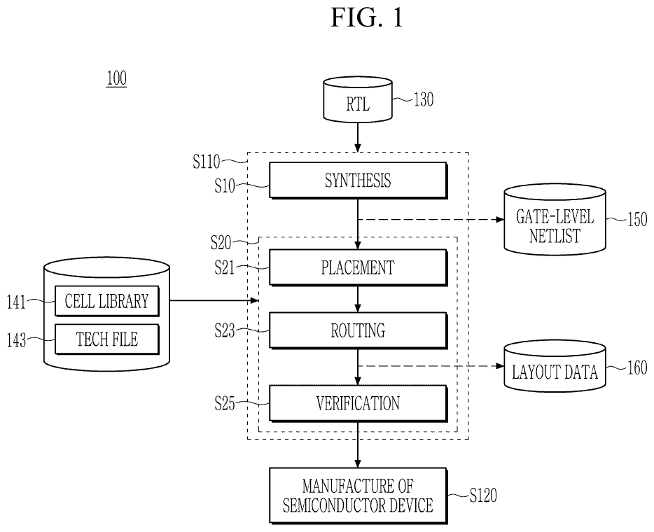

FIG. 1 is a flowchart for describing a design and manufacturing method of an example of an integrated circuit.

Referring to FIG. 1, the design and manufacturing method 100 of the integrated circuit may include a design step S110 of the integrated circuit and a manufacturing step S120 of the integrated circuit. The design step S110 of the integrated circuit may be a step of generating a gate-level netlist 150, designing layout data 160 for the circuit, and verifying the layout data, and may be performed in a design tool of the integrated circuit for designing and verifying the integrated circuit.

The design step S110 of the integrated circuit may include a logic synthesis step S10 and a physical design step S20. The logic synthesis step S10 may refer to a step of generating the gate-level netlist 150 from RTL data 130. For example, the integrated circuit design tool (e.g., a logic synthesis tool) may perform logic synthesis generating the gate-level netlist 150 (hereinafter referred to as “netlist”) from the RTL data 130 written as a hardware description language (HDL) such as a VHSIC Hardware Description Language (VHDL) and Verilog. The netlist 150 may represent a connection relationship between cells within the integrated circuit, and may refer to a logical schematic (or a logical circuit diagram).

The physical design step S20 may include a placement step S21, a routing step S23, and a verification step S25. The integrated circuit design tool may receive a cell library 141 and a tech file 143, and may perform each step based on the cell library 141 and the tech file 143.

In the placement step S21, standard cells may be placed or disposed. For example, the integrated circuit design tool (e.g., a P&R tool) may place standard cells used in the netlist 150. The integrated circuit design tool may place the standard cells along a predefined row based on information on standard cells stored in the cell library 141. The cell library 141 may include layout information such as a height or a size of the standard cell and geometric information of patterns forming the standard cell, characteristic information such as a delay current and a leakage current of the standard cell, and the like.

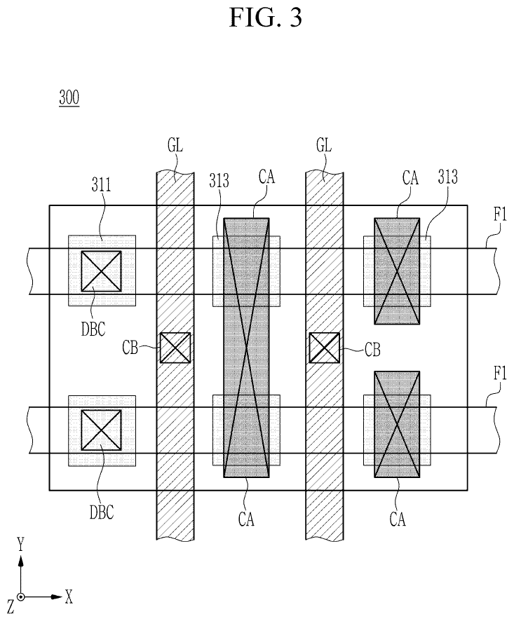

In some implementations, the cell library 141 may include layout information on a contact layer and a gate line of the standard cell. The integrated circuit design tool may generate the contact layer and the gate line as a pin of the standard cell based on the cell library 141. The contact layer may be a source/drain contact. The standard cell may be electrically connected to another standard cell through the contact layer and the gate line generated as the pin. A detailed description of the standard cell including the contact layer and the gate line will be given later with reference to FIG. 3. Here, the standard cell may include logical elements such as an AND element, an OR element, and an inverter, and memory elements such as flip-flops. The standard cell may be implemented by at least one transistor (e.g., a metal oxide semiconductor field effect transistor (MOSFET) or a FinFET), but the present disclosure is not limited thereto.

In the routing step S23, pins of the standard cells may be routed. For example, the integrated circuit design tool may electrically connect the pins of the standard cells placed in the placement step S21 based on a connection relationship of the standard cells of the netlist 150.

The integrated circuit design tool may electrically connect the pins of the standard cells using a plurality of layers. The integrated circuit design tool may generate the plurality of layers based on information stored in the tech file 143. The tech file 143 may include information on the plurality of layers and a plurality of vias. For example, the tech file 143 may define names of layers and vias, a width, a spacing, and an area of the layers and the vias according to a design rule, and the like.

In some implementations, the tech file 143 may define the contact layer and the gate line as the layer. The integrated circuit design tool may use the contact layer and the gate line as the layer electrically connecting the standard cells based on the tech file 143. The integrated circuit design tool may electrically connect the standard cells to each other using the layer electrically connected to the contact layer and the gate line among the plurality of layers. The tech file 143 may define a minimum width and a maximum width for the layers. In some implementations, the integrated circuit design tool may generate layers of various widths based on the tech file 143, and may use the layers to electrically connect the standard cells.

The plurality of layers may be formed along a plurality of tracks formed on the integrated circuit. For example, a first layer may be formed along first tracks extending in a first direction, a second layer may be formed along second tracks extending in a second direction intersecting the first direction, and a third layer may be formed along third tracks extending in the first direction. The first tracks extending in the first direction may be disposed along the second direction, and may be parallel to each other. The second tracks extending in the second direction may be disposed along the first direction, and may be parallel to each other. The third tracks extending in the first direction may be disposed along the second direction, and may be parallel to each other. The first tracks and the third tracks may be the same or different from each other.

The integrated circuit design tool may generate the layout data 160 defining the placed standard cells and the generated layers and vias. The layout data 160 may have a format such as GDSII, and may include geometric information on the cells, the layers, and the vias.

The verification step S25 may be a step of verifying and modifying the generated layout. A verification item may include a static timing analysis (STA) verifying whether the layout satisfies a timing condition of the design, a design rule check (DRC) verifying whether the layout is properly in accordance with a design rule, an electronic rule check (ERC) verifying whether the layout is properly in accordance with the design rule without internal electrical disconnection, a layout versus schematic (LVS) verifying whether the layout matches the netlist, and the like.

The manufacturing step S120 of the integrated circuit may include a plurality of steps for manufacturing a mask and forming a semiconductor package.

The manufacturing step S120 of the integrated circuit may include a step of generating mask data for forming various patterns of the plurality of layers by performing optical proximity correction (OPC) or the like on the layout data 160 generated in the design step S110 of the integrated circuit, and a step of manufacturing a mask using the mask data. In the manufacturing step S120 of the integrated circuit, various types of exposure and etching processes may be repeatedly performed. Shapes of patterns formed through the processes when the layout is designed may be sequentially formed on a silicon substrate.

Additionally, in the manufacturing step S120 of the integrated circuit, a packaging process of mounting a semiconductor device generated by the integrated circuit on a PCB and molding the semiconductor device with a molding material may be performed. The semiconductor device may be flipped or bonded on a substrate using a plurality of contact members through the packaging process.

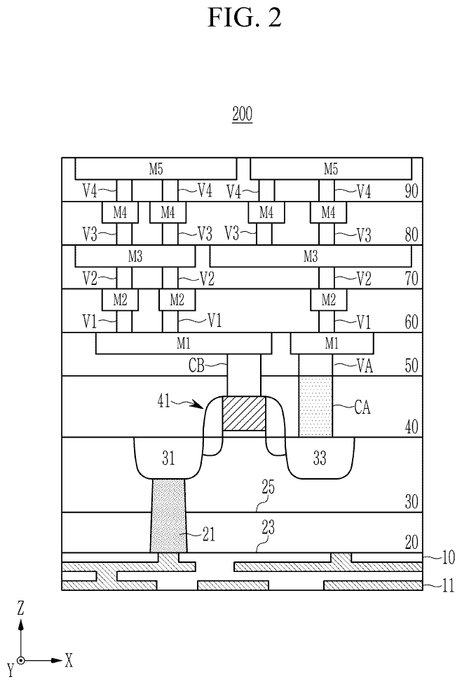

FIG. 2 is a cross-sectional view of an example of the integrated circuit.

In some implementations, the integrated circuit 200 may include a plurality of layers stacked in a third direction (e.g., a Z-direction). Referring to FIG. 2, the integrated circuit 200 may include a base insulating layer 20, an active region 30 on a first surface 25 of the base insulating layer 20, and a plurality of insulating layers 40, 50, . . . , 90 above the active region 30, and may include various patterns formed within each layer. Additionally, the integrated circuit 200 may include a backside insulating layer (or a rear surface insulating layer) 10 on a second surface 23 facing the first surface 25 of the base insulating layer 20 and a backside conductive pattern 11 formed at the backside insulating layer 10.

Referring to FIG. 2, the integrated circuit 200 may include the base insulating layer 20. The base insulating layer 20 may be an insulation substrate. The base insulating layer 20 may include oxide, nitride, oxynitride, or a combination thereof.

The integrated circuit 200 may include the active region 30. The active region 30 may be disposed on the first surface 25 of the base insulating layer 20, and may have a thickness in the third direction Z. Source/drain regions 31 and 33 may be formed at the active region 30. The source/drain regions 31 and 33 may be disposed to be spaced apart from each other in a first direction X.

The integrated circuit 200 may include the insulating layer 40 on the active region 30. The insulating layer 40 may include a gate structure 41 and a source/drain contact CA. The gate structure 41 may be disposed on the active region. The gate structure 41 may extend in a second direction Y. The gate structure 41 may be electrically connected to a plurality of layers formed on the insulating layer 40 through a gate contact CB. The gate contact CB may extend through the insulating layers 40 and 50 in the third direction Z. The gate contact CB may penetrate the insulating layers 40 and 50 to contact a first layer M1. The gate structure 41 may receive an electrical signal or the like from another standard cell through the gate contact CB, or may supply an electrical signal or the like to another standard cell. The gate structure 41 may be disposed between the source/drain regions 31 and 33. The source/drain regions 31 and 33 and the gate structure 41 may form a transistor.

The source/drain contact CA may extend in the third direction Z through the insulating layer 40. The source/drain contact CA may electrically contact the source/drain region 33. The source/drain contact CA may electrically connect a plurality of layers formed on the insulating layer 40 to the source/drain region 33 through a via VA. The source/drain region 33 may receive an electrical signal or the like from another standard cell through the source/drain contact CA, or may supply an electrical signal or the like to another standard cell.

The integrated circuit 200 may include layers disposed on the insulating layer 50, 60, . . . , 90 and electrically connecting the standard cells within the integrated circuit 200. Specifically, the integrated circuit may include layers stacked in the third direction (the Z-direction). For example, a second layer M2 may be formed above the first layer M1 among the plurality of layers. Additionally, a third layer M3 may be further formed above the second layer M2. Each layer may be connected through vias (V1, V2, . . . ) formed on the layers, and the layers and the vias may electrically connect the pins of the standard cells. The plurality of layers may extend across each other. For example, the first layer M1 among the plurality of layers may extend in the first direction X, and the second layer M2 among the plurality of layers formed above the first layer M1 may extend in the second direction Y intersecting the first direction. Additionally, the third layer M3 formed above the second layer M2 may extend in the first direction X, and a fourth layer M4 formed above the third layer M3 may extend in the second direction Y. In some implementations, each of the layers and the vias may be formed of a metal, conductive metal nitride, metal silicide, or a combination thereof, but the present disclosure is not limited thereto. The integrated circuit 200 may include more upper layers such as layers M6, M7, and the like disposed above a layer M5. A detailed description of a constituent material of each component and a formation method of each component is omitted here.

In some implementations, the integrated circuit 200 may have a backside power distribution network (BSPDN) structure in which a power distribution network for routing signals provided to the standard cells is disposed on a backside of a substrate. The integrated circuit 200 may include a backside source/drain contact 21 that electrically connects the source/drain region 31 and the backside conductive pattern 11. The backside source/drain contact 21 may penetrate the base insulating layer 20 and the active region 30 in the third direction Z. Accordingly, the backside source/drain contact 21 may contact some regions of the source/drain region 31. In some implementations, a width in a horizontal direction of the backside source/drain contact 21 may gradually decrease from the second surface 23 of the base insulating layer 20 toward the source/drain region 31. That is, the backside source/drain contact 21 may have a tapered shape along the third direction Z. The backside source/drain contact 21 may include at least one of a metal, a metal alloy, conductive metal nitride, conductive metal carbide, and conductive metal oxide, but the present disclosure is not limited thereto.

The integrated circuit 200 may include the backside insulating layer 10. The backside insulating layer 10 may be disposed on the second surface 23 of the base insulating layer 20. Some regions of an upper surface of the backside insulating layer 10 may be in contact with a lower surface of the backside source/drain contact 21. The backside insulating layer 10 may include the backside conductive pattern 11. The backside conductive pattern 11 may include conductive patterns disposed to be spaced apart from each other in the third direction Z and vias connecting two conductive patterns. In some implementations, a power source voltage or the like supplied from the outside may be provided to the source/drain region 31 through the backside conductive pattern 11 and the backside source/drain contact 21. The integrated circuit 200 may receive a power source voltage or the like from the outside through the backside conductive pattern 11 and the backside source/drain contact 21.

A structure of the integrated circuit 200 is not limited thereto. For example, the integrated circuit 200 may include an additional layer between the layers or may not include some of the layers described above, and may further include an additional component formed in each layer or may not include some of components formed in each layer described above or described below.

FIG. 3 is a layout diagram of an example of the standard cell.

Referring to FIG. 3, the standard cell 300 may be one of the plurality of standard cells included in the integrated circuit 200 of FIG. 2, and the standard cell 300 may include more components in addition to the component of FIG. 3.

The integrated circuit design tool may design the integrated circuit using the standard cell 300 generated by the cell library 141 of FIG. 1. The standard cell 300 may include a circuit pattern having a layout designed according to a placement and routing (PnR) technique to perform at least one logical function. Specifically, the standard cell 300 may include a plurality of active regions F1, a gate line GL, source/drain regions 311 and 313, and a source/drain contact CA, and the like. In some implementations, the gate line GL and the source/drain contact CA of the standard cell 300 may correspond to the pin of the standard cell 300. Specifically, the integrated circuit design tool may generate the gate line GL and/or the source/drain contact CA of the standard cell 300 as the pin of the standard cell 300 based on the cell library 141. For example, the integrated circuit design tool may generate the gate line GL as a first pin of the standard cell 300, and may generate the source/drain contact CA as a second pin of the standard cell 300. The first pin may correspond to an input pin, and the second pin may correspond to an output pin, but the present disclosure is not limited thereto.

Referring to FIG. 3, the standard cell 300 may include the plurality of active regions F1. The plurality of active regions F1 may extend in the first direction X, and may be disposed along the second direction Y. The plurality of active regions F1 may be parallel to each other. Active patterns formed at the plurality of active regions F1 may intersect the gate line GL to form a transistor.

A plurality of gate lines GL may be disposed above the plurality of active regions F1. Each of the plurality of gate lines GL may extend in the second direction Y intersecting the first direction X. The plurality of gate lines GL may overlap at least a portion of the plurality of active regions F1 on an XY plane. The gate line GL may include any material having electrical conductivity. A gate contact CB may be disposed on the gate line GL. The gate line GL may be electrically connected to a plurality of layers within the integrated circuit 200 through the gate contact CB. The standard cell 300 may transmit and receive a logical signal to and from another standard cell through the gate line GL, the gate contact CB, and the plurality of layers. The gate line GL of the standard cell 300 may correspond to a signal pin of the standard cell 300.

The plurality of source/drain regions 311 and 313 may be formed at the plurality of active regions F1, and a plurality of source/drain contacts CA contacting the source/drain region 313 may be formed. The source/drain contact CA may be electrically connected to a portion of the source/drain region 313 among the plurality of source/drain regions 311 and 313 formed in the plurality of active regions F1. The source/drain contact CA may extend in the third direction Z from the plurality of active regions F1. The source/drain contact CA may electrically connect the plurality of layers within the integrated circuit 200 to the source/drain region 313 through a via. Hereinafter, the source/drain contact CA disposed in the third direction Z from the plurality of active regions F1 may be referred to as a frontside source/drain contact. The standard cell 300 may transmit/receive a logical signal to/from another standard cell through the source/drain region 313, the frontside source/drain contact CA, and the plurality of layers. The source/drain region 313 connected to the frontside source/drain contact CA among the plurality of source/drain regions 311 and 313 of the standard cell 300 may correspond to the signal pin of the standard cell 300.

A backside source/drain contact DBC may be formed in a direction opposite to the frontside source/drain contact CA based on the plurality of source/drain regions 311 and 313. The backside source/drain contact DBC may be electrically connected to a portion of the source/drain region 311 among the plurality of source/drain regions 311 and 313 formed in the plurality of active regions F1. The backside source/drain contact DBC may electrically connect the source/drain region 311 and the backside conductive pattern 11 of FIG. 2. The source/drain region 311 of the standard cell 300 may receive a power source voltage and/or a ground voltage from the backside conductive pattern 11 through the backside source/drain contact DBC. The source/drain region 311 connected to the backside source/drain contact DBC among the plurality of source/drain regions 311 and 313 of the standard cell 300 may correspond to a power pin of the standard cell 300.

Each of the plurality of source/drain regions 311 and 313 may be connected to one of the frontside source/drain contact CA and the backside source/drain contact DBC.

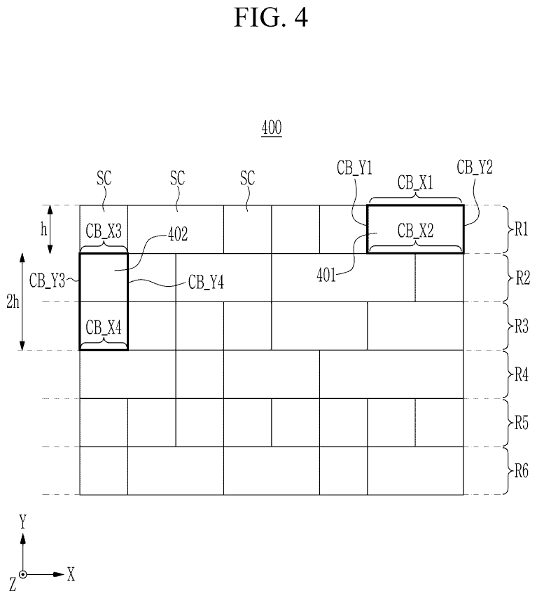

FIG. 4 is a layout diagram of an example of an integrated circuit.

Referring to FIG. 4, the integrated circuit 400 may include a plurality of standard cells SC including circuit patterns for forming various circuits. The plurality of standard cells SC may have a function performing various logical functions. In some implementations, the plurality of standard cells SC may include logical elements such as an AND element, an OR element, and an inverter and memory elements such as a latch and a flip-flop, or the like, or may be one thereof. Although not shown here, the integrated circuit 400 may further include physical cells such as filler cells.

The standard cell SC may include a cell boundary. A size of the standard cell SC may be determined by the cell boundary. Specifically, the standard cell SC may be limited by the cell boundary, and the integrated circuit design tool may recognize the standard cell SC using the cell boundary. For example, the cell boundary of a first standard cell 401 may include cell boundaries CB_X1 and CB_X2 in the first direction X and cell boundaries CB_Y1 and CB_Y2 in the second direction Y that is perpendicular to the first direction X. Additionally, the cell boundary of a second standard cell 402 may include cell boundaries CB_X3 and CB_X4 in the first direction X and cell boundaries CB_Y3 and CB_Y4 in the second direction Y.

The integrated circuit design tool may predefine a plurality of rows R1, R2, . . . , R6 extending in the first direction X on the integrated circuit 400. Each of the plurality of rows R1, R2, . . . , R6 may extend in the first direction X, and may be disposed along the second direction Y. The plurality of rows R1, R2, . . . , R6 may be a region in which the standard cells are disposed. The integrated circuit design tool may dispose the plurality of standard cells SC along the plurality of rows R1, R2, . . . , R6.

Heights in the second direction Y of the plurality of standard cells SC may be the same or different from each other. Specifically, the heights in the second direction Y of the plurality of standard cells SC may be determined according to lengths in the second direction Y of the rows in which the standard cells are disposed. For example, a height h in the second direction Y of the first standard cell 401 may be equal to a length in the second direction Y of the first row R1 in which the first standard cell 401 is disposed. Hereinafter, the standard cell may be referred to as a single row cell. Alternatively, a height 2h in the second direction Y of the second standard cell 402 may be equal to lengths in the second direction Y of the plurality of rows R2 and R3 in which the second standard cell 402 is disposed. Hereinafter, the standard cell may be referred to as a multi-row cell. However, the present disclosure is not limited thereto, and the multi-row cell may include standard cells with a cell height of 3h or more.

FIG. 4 shows the integrated circuit 400 including six rows R1, R2, . . . , R6, but this is only an example, the integrated circuit 400 may include various numbers of rows, and one row may include various numbers of standard cells.

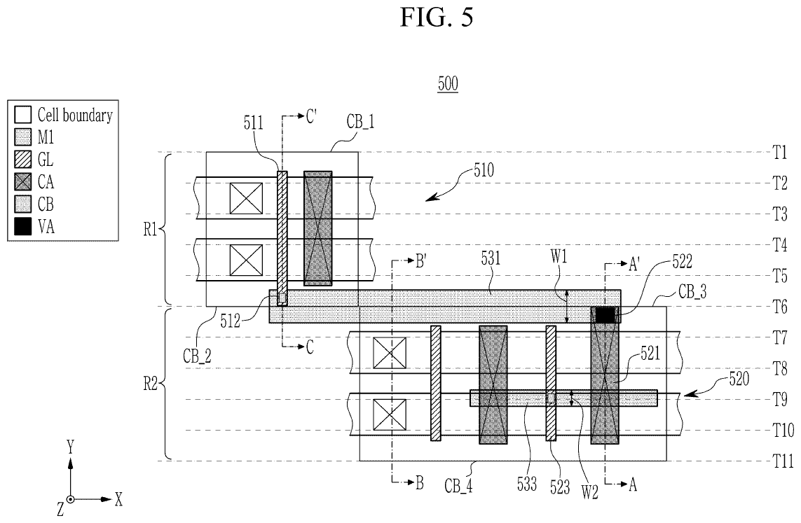

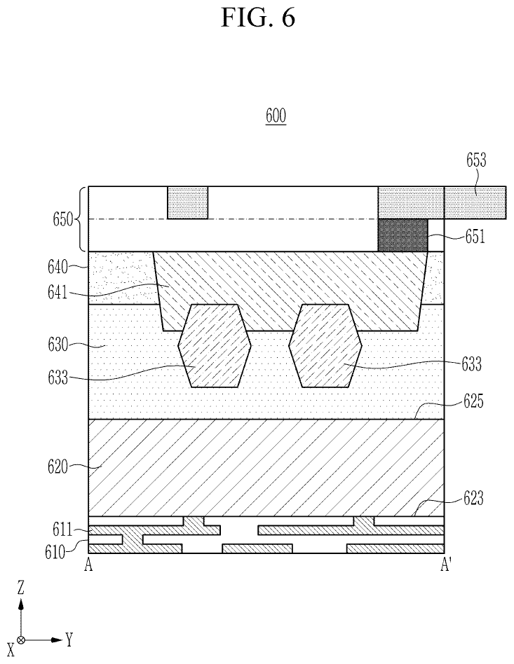

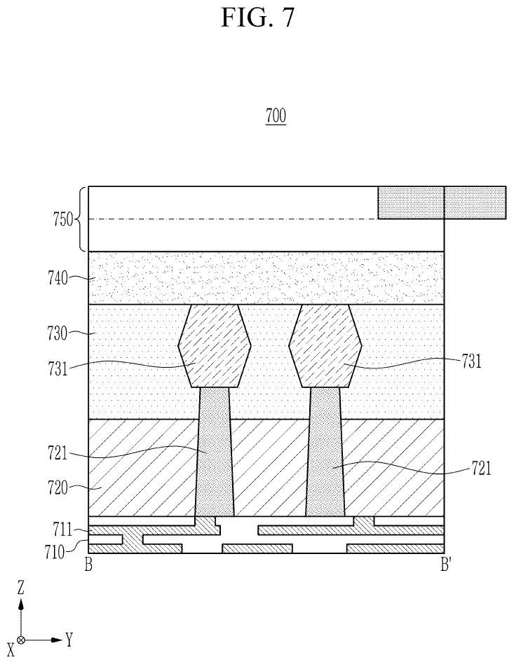

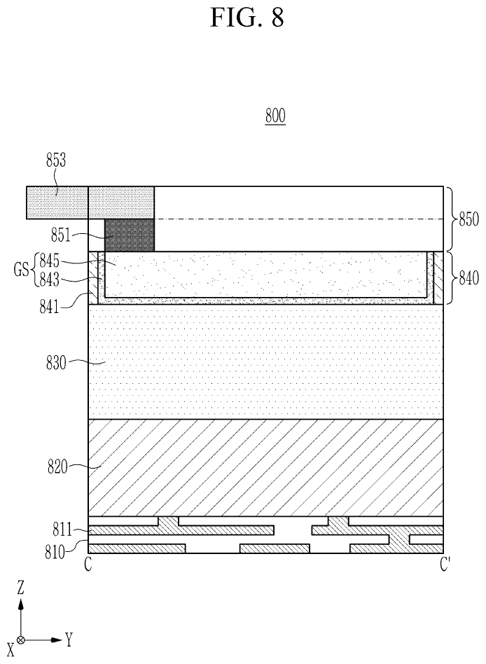

FIG. 5 is a layout diagram of an example of an integrated circuit, FIG. 6 is a cross-sectional view of an example of the integrated circuit along a line A-A′ of FIG. 5, FIG. 7 is a cross-sectional view of an example of the integrated circuit along a line B-B′ of FIG. 5, and FIG. 8 is a cross-sectional view of an example of the integrated circuit along a line C-C′ of FIG. 5.

In some implementations, a plurality of tracks at which the first layer M1 is disposed may be defined on the integrated circuit 500. For example, a plurality of tracks T1, T2, . . . , T11 extending in the first direction X may be defined on the integrated circuit 500. The plurality of tracks T1, T2, . . . , T11 may extend in the first direction X, and may be disposed along the second direction Y. The plurality of tracks T1, T2, . . . , T11 may be parallel to each other. A first layer M1 may be disposed along the plurality of tracks T1, T2, . . . , T11 extending in the first direction X. For example, the first layer M1 may overlap the plurality of tracks T1, T2, . . . , T11 extending in the first direction X on an XY plane.

In some implementations, some tracks T1, T6, and T11 among the plurality of tracks T1, T2, . . . , T11 may overlap cell boundaries CB_1, CB_2, CB_3, and CB_4 in the first direction X of standard cells 510 and 520, and the remaining tracks T2 to T5 and T7 to T10 may be disposed between the cell boundaries CB_1, CB_2, CB_3, and CB_4 in the first direction X of the standard cells 510 and 520.

In some implementations, the integrated circuit 500 may include the first standard cell 510 and the second standard cell 520. The first standard cell 510 and the second standard cell 520 may be disposed along a plurality of rows. Specifically, the first standard cell 510 may be disposed along a first row R1, and the second standard cell 520 may be disposed along a second row R2. However, the present disclosure is not limited thereto, and the first standard cell 510 and the second standard cell 520 may be disposed in a row spaced apart from each other in the second direction Y, or may be disposed along the same row. Heights in the second direction Y of the first standard cell 510 and the second standard cell 520 may be the same or different from each other.

In some implementations, the standard cells of the integrated circuit 500 may include a gate line GL and a contact layer CA generated as a pin. The standard cells of the integrated circuit 500 may include the gate line GL and the contact layer CA generated as the pin and extending in the second direction Y. Specifically, a gate line 511 of the first standard cell 510 may correspond to a first pin of the first standard cell 510. For example, the gate line 511 of the first standard cell 510 may correspond to an input pin of the first standard cell 510. Alternatively, a gate line 523 of the second standard cell 520 may correspond to a first pin of the second standard cell 520, and a contact layer 521 of the second standard cell 520 may correspond to a second pin of the second standard cell 520. For example, the gate line 523 of the second standard cell 520 may correspond to an input pin of the second standard cell 520, and the contact layer 521 of the second standard cell 520 may correspond to an output pin of the second standard cell 520.

In some implementations, the first standard cell 510 and the second standard cell 520 may be electrically connected to each other. For example, an output signal of the second standard cell 520 may be provided as an input signal to the first standard cell 510. Therefore, the gate line 511 corresponding to the first pin of the first standard cell 510 and the contact layer 521 corresponding to the second pin of the second standard cell 520 may be electrically connected. In some implementations, the gate line 511 of the first standard cell 510 and the contact layer 521 of the second standard cell 520 may be electrically connected to each other through a first layer 531. The gate line 511 of the first standard cell 510 and the contact layer 521 of the second standard cell 520 may be electrically connected to each other through the first layer 531 extending in the first direction X. Specifically, the gate line 511 of the first standard cell 510 may be connected to the first layer 531 via a gate contact 512, and the contact layer 521 of the second standard cell 520 may be connected to the first layer 531 via a via 522. The integrated circuit design tool may electrically connect the first standard cell 510 and the second standard cell 520 using the gate line 511, the contact layer 521, and the first layer 531. However, the present disclosure is not limited thereto, and the integrated circuit design tool may electrically connect the first standard cell 510 and the second standard cell 520 using the gate line 511, the contact layer 521, and upper layers (e.g., M2 and the like) of the first layer 531 connected to the first layer 531. For example, the contact layer 521 of the second standard cell 520 may be connected to the first layer 531, the first layer 531 may be connected to the second layer M2 extending in the second direction Y, and the second layer M2 may be connected to a first layer M1 that is connected to the gate line 511 of the first standard cell 510.

In some implementations, the first layer 531 may overlap one of the plurality of cell boundaries in the first direction X of the plurality of standard cells included in the integrated circuit 500. Alternatively, a position in the second direction Y of the first layer 531 may be the same as a position in the second direction Y of the one of the plurality of cell boundaries in the first direction X of the plurality of standard cells included in the integrated circuit 500. The first layer 531 may be disposed along a track overlapping the one of the plurality of cell boundaries in the first direction X of the plurality of standard cells included in the integrated circuit 500 among the plurality of tracks.

In some implementations, the first layer 531 may be disposed along the cell boundaries CB_2 and CB_3 in the first direction X of the first standard cell 510 and the second standard cell 520. The first layer 531 may overlap the cell boundaries CB_2 and CB_3 in the first direction X of the first standard cell 510 and the second standard cell 520. Positions in the second direction Y of the cell boundary CB_2 of the first standard cell 510 and the cell boundary CB_3 of the second standard cell 520 may be substantially the same. The position in the second direction Y of the first layer 531 may be the same as the positions in the second direction Y of the cell boundary CB_2 of the first standard cell 510 and the cell boundary CB_3 of the second standard cell 520. In some implementations, the first layer 531 may be disposed along the sixth track T6 overlapping the cell boundaries CB_2 and CB_3 of the first standard cell 510 and the second standard cell 520 among the plurality of tracks T1, T2, . . . , T11.

According to some implementations, the integrated circuit design tool may use only a minimum layer to electrically connect the standard cells. Therefore, there is an advantage of improving routing congestion of the integrated circuit and optimizing an area of the integrated circuit. Additionally, because the routing congestion of the integrated circuit is improved, there is an advantage of improving a turnaround time (TAT).

In some implementations, the second standard cell 520 may be further electrically connected to another standard cell. For example, the second standard cell 520 may receive a logical signal from the other standard cell through a first layer 533 and the gate line 523. The first layer 533 may be disposed along the ninth track T9. A position in the second direction Y of the ninth track T9 may be different from positions in the second direction Y of the cell boundaries CB_3 and CB_4 in the first direction X of the second standard cell 520. The ninth track T9 may be disposed between the cell boundaries CB_3 and CB_4 in the first direction X of the second standard cell 520. A position in the second direction Y of the ninth track T9 may be disposed between the cell boundaries CB_3 and CB_4 in the first direction X of the second standard cell 520 in the second direction Y. The ninth track T9 may be one of the plurality of tracks T7, T8, T9, and T10 that the gate line 523 overlaps on an XY plane.

In some implementations, the first layer 531 disposed on the sixth track T6 that overlaps the cell boundaries CB_2 and CB_3 in the first direction X of the standard cells 510 and 520 may have a first width W1, and the first layer 533 disposed on the ninth track T9 may have a second width W2. The width of the first layer may refer to a width in the second direction Y of the first layer. In some implementations, the first width W1 may be larger than the second width W2. A width of the first layer disposed on the track that overlaps the cell boundaries of the standard cells may be relatively larger than a width of the first layer disposed on the track that does not overlap the cell boundaries of the standard cells.

In some implementations, the integrated circuit design tool may dispose the first layer included in a specific path among a plurality of paths through which a logical signal is transferred on the track that overlaps the cell boundaries of the standard cells. The integrated circuit design tool may generate a large width of the first layer included in the specific path among the plurality of paths through which the logical signal is transferred. For example, the specific path may be a path with a relatively fast timing compared with another path or a path with a relatively high resistance compared with another path, but the present disclosure is not limited thereto. The width of the first layer may be a value between a minimum width and a maximum width of the first layer defined in the tech file 143 of FIG. 1.

Hereinafter, the cross-sectional views of the integrated circuit along the lines A-A′, B-B′, and C-C′ will be described.

Referring to FIG. 6, the integrated circuit 600 may include a base insulating layer 620, an active region 630 on a first surface 625 of the base insulating layer 620, and a plurality of insulating layers 640 and 650 above the active region 630, and may include various patterns formed within each layer. Additionally, the integrated circuit 600 may include a backside insulating layer 610 on a second surface 623 facing the first surface 625 of the base insulating layer 620 and a backside conductive pattern 611 formed on the backside insulating layer 610. A description of a structure of the integrated circuit 600 that overlaps the description with reference to FIG. 2 is omitted here.

In some implementations, a plurality of source/drain regions 633 formed at the active region 630 and disposed to be spaced apart from each other in the second direction Y may be connected to a via 651 through a contact layer 641 extending in the second direction Y. For example, the contact layer 641 may correspond to the output pin of the second standard cell 520 of FIG. 5 within the integrated circuit 500 of FIG. 5. The contact layer 641 may be generated as the output pin of the second standard cell 520. The contact layer 641 may be electrically connected to a first layer 653 through the via 651. The second standard cell 520 may output a logical signal through the contact layer 641, the via 651, and the first layer 653.

Referring to FIG. 7, a plurality of source/drain regions 731 formed at an active region 730 within the integrated circuit 700 may receive a power source voltage and/or a ground voltage or the like from a backside conductive pattern 711 formed at a backside insulating layer 710 through a plurality of backside source/drain contacts 721 penetrating a base insulating layer 720 and the active region 730. Because the second standard cell 520 of FIG. 5 receives a power voltage or the like from the backside conductive pattern 711 through the backside source/drain contact 721, a plurality of layers formed above the insulating layers 740 and 750 may not supply a power voltage or the like to the second standard cell 520.

Referring to FIG. 8, an insulating layer 840 within an integrated circuit 800 may include a gate structure GS extending in the second direction Y. The gate structure GS may include a gate electrode 845 and a gate insulating film 843, and the gate insulating film 843 may extend along a side surface of a gate spacer 841.

In some implementations, the gate electrode 845 included in the gate structure GS may be connected to a first layer 853 through a gate contact 851. For example, the gate electrode 845 may correspond to the input pin of the first standard cell 510 of FIG. 5 within the integrated circuit 500 of FIG. 5. The gate electrode 845 may be generated as the input pin of the first standard cell 510. The gate electrode 845 may be electrically connected to the first layer 853 through the gate contact 851 formed at the insulating layer 850. The first standard cell 510 may receive a logical signal through the gate electrode 845, the gate contact 851, and the first layer 853.

Although the standard cells 510 and 520 are illustrated as being formed as FinFETs, the active patterns formed on the active regions within the standard cells 510 and 520 may be formed in various shapes. For example, the standard cells 510 and 520 may be formed as a gate-all-around (GAA) transistor in which a nanowire is surrounded by a gate line on the active region, or may be formed as a multi-bridge-channel (MBC) transistor in which a plurality of nanosheets are stacked on the active region and a gate line surrounds the nanosheets, but the present disclosure is not limited thereto.

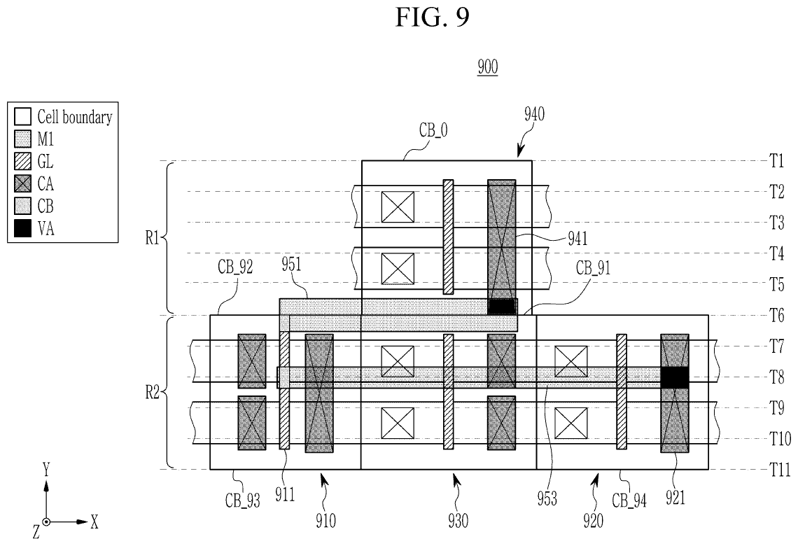

FIG. 9 is a layout diagram of an example of an integrated circuit.

Referring to FIG. 9, the integrated circuit 900 may include a first standard cell 910 and a fourth standard cell 940. The first standard cell 910 and the fourth standard cell 940 may be disposed along a plurality of rows R1 and R2. Specifically, the first standard cell 910 may be disposed along the second row R2, and the fourth standard cell 940 may be disposed along the first row R1. In some implementations, a position in the second direction Y of one cell boundary CB_92 of a plurality of cell boundaries CB_92 and CB_93 in the first direction X of the first standard cell 910 may be the same as a position in the second direction Y of one cell boundary CB_91 of a plurality of cell boundaries CB_90 and CB_91 in the first direction X of the fourth standard cell 940. However, the present disclosure is not limited thereto, and the first standard cell 910 and the fourth standard cell 940 may be disposed in a row spaced apart from each other in the second direction Y, or may be disposed in the same row. Heights in the second direction Y of the first standard cell 910 and the fourth standard cell 940 may be the same or different from each other.

In some implementations, the first standard cell 910 and the fourth standard cell 940 may be electrically connected to each other. For example, an output signal of the fourth standard cell 940 may be provided as an input signal of the first standard cell 910. Therefore, a gate line 911 corresponding to a first pin of the first standard cell 910 and a contact layer 941 corresponding to a second pin of the fourth standard cell 940 may be electrically connected. In some implementations, the gate line 911 of the first standard cell 910 and the contact layer 941 of the fourth standard cell 940 may be electrically connected to each other through a first layer 951 extending in the first direction X. The integrated circuit design tool may electrically connect the first standard cell 910 and the fourth standard cell 940 using the gate line 911, the contact layer 941, and the first layer 951. However, the present disclosure is not limited thereto, and the integrated circuit design tool may electrically connect the first standard cell 910 and the fourth standard cell 940 using the gate line 911, the contact layer 941, and upper layers (e.g., M2 and the like) of the first layer 951 that are connected to the first layer 951.

In some implementations, the first layer 951 may overlap one of the plurality of cell boundaries in the first direction X of the plurality of standard cells included in the integrated circuit 900. Alternatively, a position in the second direction Y of the first layer 951 may be the same as a position in the second direction Y of the one of the plurality of cell boundaries in the first direction X of the plurality of standard cells included in the integrated circuit 900. The first layer 951 may be disposed along a track overlapping the one of the plurality of cell boundaries in the first direction X of the plurality of standard cells included in the integrated circuit 900 among a plurality of tracks.

In some implementations, the first layer 951 may be disposed along the cell boundaries CB_92 and CB_91 of the first standard cell 910 and the fourth standard cell 940. In some implementations, the first layer 951 may be disposed along a sixth track T6 overlapping the cell boundaries CB_92 and CB_91 of the first standard cell 910 and the fourth standard cell 940 among the plurality of tracks T1, T2, . . . , T11.

In some implementations, the integrated circuit 900 may include a second standard cell 920. The integrated circuit 900 may further include a third standard cell 930 disposed between the first standard cell 910 and the second standard cell 920 in the first direction X. The second standard cell 920 and the third standard cell 930 may be disposed along the row. Specifically, the second standard cell 920 and the third standard cell 920 may be disposed along the second row R2. Although it is illustrated that the second standard cell 920 and the third standard cell 930 are disposed along the same row, the present disclosure is not limited thereto.

In some implementations, the first standard cell 910 and the second standard cell 920 may be electrically connected to each other. For example, an output signal of the second standard cell 920 may be provided as an input signal of the first standard cell 910. Therefore, the gate line 911 corresponding to an input pin of the first standard cell 910 and a contact layer 921 corresponding to an output pin of the second standard cell 920 may be electrically connected.

In some implementations, the gate line 911 of the first standard cell 910 and the contact layer 921 of the second standard cell 920 may be electrically connected through a first layer 953. The first layer 953 may be disposed along a track that simultaneously overlaps the gate line 911 of the first standard cell 910 and the contact layer 921 of the second standard cell 920. Although the first layer 953 is illustrated as being disposed along the eighth track T8, the present disclosure is not limited thereto. For example, the first layer 953 may be disposed between the cell boundaries CB_92 and CB_93 in the first direction X of the first standard cell 910, and may be disposed along any track (e.g., T7, T9, or T10) that simultaneously overlaps the gate line 911 of the first standard cell 910 and the contact layer 921 of the second standard cell 920. A position in the second direction Y of the first layer 953 may be different from a position in the second direction Y of the cell boundaries CB_92 and CB_93 in the first direction X of the first standard cell 910. The first standard cell 910 and the second standard cell 920 may be electrically connected through the gate line 911, the contact layer 921, and the first layer 953. Although it is illustrated that the first standard cell 910 and the second standard cell 920 are disposed along the same row R2, the present disclosure is not limited thereto. For example, the first standard cell 910 and the second standard cell 920 may be disposed along different rows. Heights in the second direction Y of the first standard cell 910 and the second standard cell 920 may be the same or different from each other.

In some implementations, a logical signal transmitted and received between the first standard cell 910 and the fourth standard cell 940 may be a signal having a relatively faster timing than that of a logical signal transmitted and received between the first standard cell 910 and the second standard cell 920. Alternatively, a path between the first standard cell 910 and the fourth standard cell 940 may be a path with a relatively lower resistance than that of a path between the first standard cell 910 and the second standard cell 920.

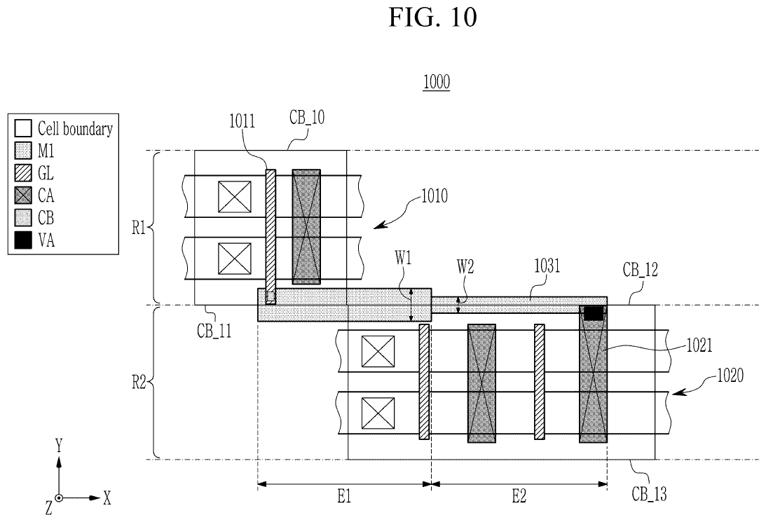

FIG. 10 is a layout diagram of an example of an integrated circuit.

Referring to FIG. 10, the integrated circuit 1000 may include a first standard cell 1010 and a second standard cell 1020. The first standard cell 1010 may be disposed along a first row R1, and the second standard cell 1020 may be disposed along a second row R2. In some implementations, a position in the second direction Y of one cell boundary CB_11 among a plurality of cell boundaries CB_10 and CB_11 in the first direction X of the first standard cell 1010 and a position in the second direction Y of one cell boundary CB_12 among a plurality of cell boundaries CB_12 and CB_13 in the first direction X of the second standard cell 1020 may be the same. However, the present disclosure is not limited thereto, and the first standard cell 1010 and the second standard cell 1020 may be disposed in a row spaced apart from each other in the second direction Y, or may be disposed along the same row.

In some implementations, the first standard cell 1010 and the second standard cell 1020 may be electrically connected to each other. Specifically, a gate line 1011 corresponding to an input pin of the first standard cell 1010 and a contact layer 1021 corresponding to an output pin of the second standard cell 1020 may be electrically connected through a first layer 1031. The first layer 1031 may overlap one of the plurality of cell boundaries in the first direction X of the plurality of standard cells included in the integrated circuit 1000. In some implementations, the first layer 1031 may be disposed along the cell boundary CB_11 in the first direction X of the first standard cell 1010, and may be disposed along the cell boundary CB_12 in the first direction X of the second standard cell 1020. The first layer 1031 may overlap the cell boundary CB_11 in the first direction X of the first standard cell 1010 and the cell boundary CB_12 in the first direction X of the second standard cell 1020.

In some implementations, a width of the first layer 1031 connected between the gate line 1011 of the first standard cell 1010 and the contact layer 1021 of the second standard cell 1020 may vary depending on a section. Specifically, the first layer 1031 may have a first width W1 in a first section E1, and may have a second width W2 in a second section E2. For example, the integrated circuit design tool may differently determine the width of the first layer 1031 in each section to reduce a resistance of the first layer 1031 in the first section E1 and improve coupling capacitance with another layer adjacent to the first layer 1031 in the second section E2. The widths W1 and W2 of the first layer 1031 may be values between a minimum width and a maximum width of the first layer defined in the tech file 143 of FIG. 1.

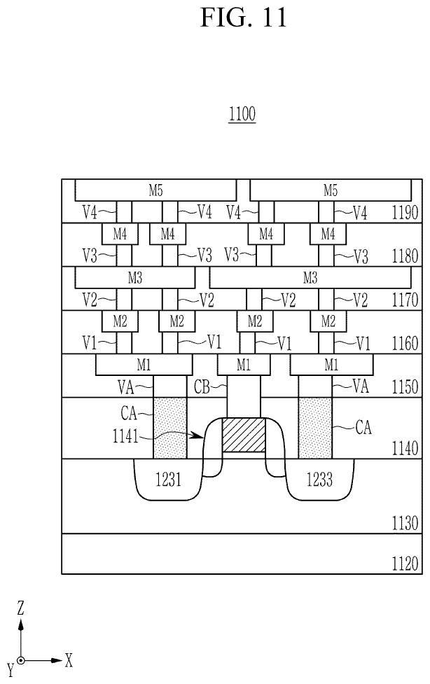

FIG. 11 is a cross-sectional view of an example of an integrated circuit.

The integrated circuit 1100 may have a frontside power distribution network (FSPDN) structure that disposes a power distribution network on a frontside of a substrate for routing signals provided to the standard cells.

Referring to FIG. 11, the integrated circuit 1100 may include a plurality of layers stacked in the third direction Z. Specifically, the integrated circuit 1100 may include a base insulating layer 1120, an active region 1130 on the base insulating layer 1120, and a plurality of insulating layers 1140, 1150, . . . , 1190 above the active region 1130, and may include various patterns formed within each layer. A description of a structure of the integrated circuit 1100 that overlaps the structure of the integrated circuit 200 of FIG. 2 is omitted here.

In some implementations, a plurality of source/drain regions 1231 and 1233 formed at the active region 1130 within the integrated circuit 1100 may be electrically connected to a plurality of layers through a contact layer CA and a plurality of vias (VA, V1, . . . ) formed at the plurality of insulating layers 1140, 1150, . . . , 1190. At least one source/drain region (e.g., 1231) among the plurality of source/drain regions 1231 and 1233 may receive a power source voltage and/or a ground voltage via a power distribution network disposed on a frontside of the base insulating layer 1120. Another source/drain region (e.g., 1233) among the plurality of source/drain regions 1231 and 1233 may transmit and receive a logical signal through the power distribution network disposed on the frontside of the base insulating layer 1120. The plurality of source/drain regions 1231 and 1233 may receive a power source voltage and/or a logic signal or the like through a plurality of layers included in the plurality of insulating layers 1140, 1150, . . . , 1190.

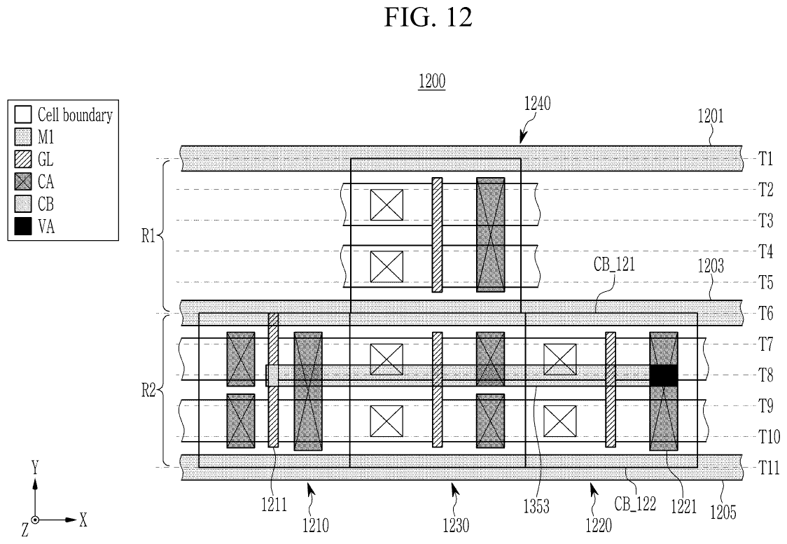

FIG. 12 is a layout diagram of an example of an integrated circuit. Specifically, the integrated circuit 1200 may be the FSPDN structure according to FIG. 11.

In some implementations, the integrated circuit 1200 may include a plurality of rows R1 and R2 extending in the first direction X. In some implementations, the integrated circuit 1200 may include a plurality of standard cells 1210 to 1240 disposed along the plurality of rows R1 and R2. In some implementations, the plurality of standard cells 1210 to 1240 may receive a power supply voltage or the like through a plurality of first layers 1201, 1203, and 1205. Specifically, the power supply voltage or the like supplied from the outside may be transferred to the plurality of first layers 1201, 1203, and 1205 through a plurality of layers (e.g., M2, M3, M4, and M5 of FIG. 11, M6 and M7 that are not shown but are disposed above M5 of FIG. 11, and the like), and the plurality of standard cells 1210 to 1240 may receive the power supply voltage or the like through the plurality of first layers 1201, 1203, and 1205.

In some implementations, the first standard cell 1210 and the second standard cell 1220 may be disposed along the second row R2. However, the present disclosure is not limited thereto, and rows in which the first standard cell 1210 and the second standard cell 1220 are disposed may be different from each other. Heights in the second direction Y of the first standard cell 1210 and the second standard cell 1220 may be the same or different from each other. In some implementations, a third standard cell 1230 may be disposed between the first standard cell 1210 and the second standard cell 1220 in the first direction X. The third standard cell 1230 is shown as being disposed along the second row R2, but the present disclosure is not limited thereto.

In some implementations, the first standard cell 1210 and the second standard cell 1220 may be electrically connected to each other. For example, a gate line 1211 of the first standard cell 1210 and a contact layer 1221 of the second standard cell 1220 may be electrically connected to each other through a first layer 1353. The integrated circuit design tool may electrically connect the first standard cell 1210 and the second standard cell 1220 using the gate line 1211, the contact layer 1221, and the first layer 1353.

In some implementations, the first layer 1353 may be disposed along a track that simultaneously overlaps the gate line 1211 of the first standard cell 1210 and the contact layer 1221 of the second standard cell 1220. In some implementations, a position of the first layer 1353 in the second direction Y may be different from a position in the second direction Y of cell boundaries CB_121 and CB_122 in the first direction X of the second standard cell 1220. The position of the first layer 1353 in the second direction Y may be disposed between the cell boundaries CB_121 and CB_122 in the first direction X of the second standard cell 1220 in the second direction Y. Here, the first layer 1353 is illustrated as being disposed along an eighth track T8, but the present disclosure is not limited thereto. For example, the first layer 1353 may be disposed between the cell boundaries CB_121 and CB_122 in the first direction X of the second standard cell 1220 in the second direction Y, and may be disposed along any track T7, T9, or T10 that simultaneously overlaps the gate line 1211 of the first standard cell 1210 and the contact layer 1221 of the second standard cell 1220.

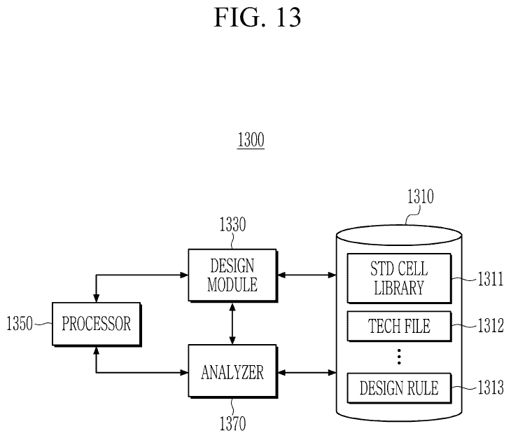

FIG. 13 is a view schematically showing a design system of an example of the integrated circuit.

The design system 1300 may include a storage device 1310, a design module 1330, a processor 1350, and an analyzer (or an analysis module) 1370. The design system 1300 of FIG. 13 may perform at least some of a design operation of the integrated circuit described in the design methods of the integrated circuits of FIGS. 1 to 12. The design system 1300 may be implemented as an integrated device so that it is referred to as a design device. The design system 1300 may be provided as a dedicated device for designing the integrated circuit, but may also be a computer for driving various simulation tools or design tools.

According to some implementations, the storage device 1310 may include a standard cell library 1311, a tech file 1312, and a design rule 1313. In some implementations, the standard cell library 1311 may include layout information on the standard cell, and the tech file 1312 may include information on a plurality of layers within the integrated circuit. The standard cell library 1311, the tech file 1312, and the design rule 1313 within the storage device 1310 may be provided from the storage device 1310 to the design module 1330 and the analyzer 1370. The number of standard cell libraries included in the storage device 1310 may be variously changed.

According to some implementations, the design module 1330 may receive the standard cell library 1311, the tech file 1312, and the design rule 1313 from the storage device 1310 to perform design operations of the integrated circuits of FIGS. 1 to 12. In some implementations, the design module 1330 may generate the standard cell using the standard cell library 1311, and may perform a disposition operation on the standard cell. Specifically, the design module may generate the gate line and the contact layer as a pin of the standard cells based on the standard cell library 1311. The standard cell library 1311 may include layout information on the gate line and the contact layer extending in the first direction as the pin of the standard cell. In some implementations, the design module 1330 may generate the plurality of layers based on the tech file 1312, and then may perform a routing operation on the standard cells. In some implementations, the tech file 1312 may be a layer electrically connecting the standard cells, and may include information on the gate line and the contact layer. The design module 1330 may use the gate line and the contact layer to perform the routing operation on the standard cells based on the tech file 1312. Specifically, the design module 1330 may electrically connect the standard cells using the gate line, the contact layer, and a first layer connected to the gate line and the contact layer. Here, the term “module” may refer to software, hardware such as a field programmable gate array (FPGA) or an application specific integrated circuit (ASIC), or a combination of software and hardware.

The processor 1350 may be used by the design module 1330 and the analyzer 1370 to perform a calculation. For example, the processor 1350 may include a microprocessor, an application processor (AP), a digital signal processor (DSP), a graphic processing unit (GPU), or the like. Although FIG. 13 shows only one processor 1350, the design system 1300 may include a plurality of processors. The processor 1350 may include a cache memory to improve calculation ability.

The analyzer 1370 may perform analysis and verification on a layout generated by the design module 1330 during or after performing the design operations of the integrated circuits of FIGS. 1 to 11. In some implementations, the analyzer 1370 may analyze and verify whether the standard cells and a plurality of metal layers connecting the standard cells satisfy the design rule based on the design rule 1313 received from the storage device 1310.

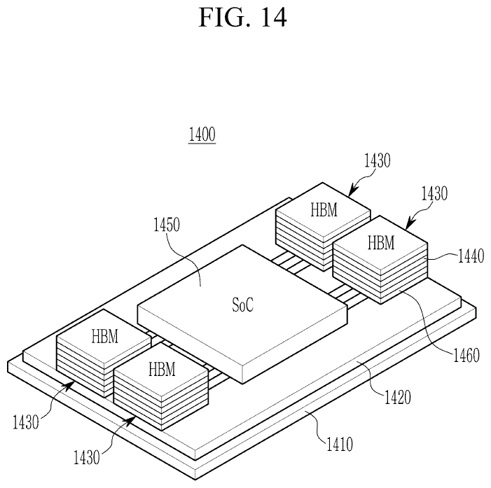

FIG. 14 is a view showing an example of a semiconductor device.

Referring to FIG. 14, the semiconductor device 1400 may be a memory module including at least one stack semiconductor chip 1430 and a system-on-chip (SOC) 1450 mounted above a package substrate 1410 such as a printed circuit board.

An interposer 1420 may be selectively provided on the package substrate 1410. The stack semiconductor chip 1430 may be formed as a chip-on-chip (CoC). The stack semiconductor chip 1430 may include at least one memory chip 1440 stacked on a buffer chip 1460 such as a logic chip. The buffer chip 1460 and the at least one memory chip 1440 may be connected to each other by a through-silicon via (TSV). In some implementations, the buffer chip 1460, the at least one memory chip 1440, and the system-on-chip 1450 may be designed by the layout method described with reference to FIGS. 1 to 12. Specifically, the standard cells within the chip may be electrically connected through the gate line and the contact layer generated as a pin and a first layer connected to the gate line and the contact layer. In some implementations, the first layer may be disposed along a track that overlaps one of a plurality of cell boundaries in the first direction of the electrically connected standard cells. Alternatively, the first layer may be disposed along one of a plurality of tracks that simultaneously overlap the gate line and the contact layer of the electrically connected standard cells. In some implementations, the semiconductor device 1400 may have a backside power distribution network structure. In some implementations, the semiconductor device 1400 may have a frontside power distribution network structure. In some implementations, the stack semiconductor chip 1430 may be a high band memory (HBM) of 500 GB/sec to 1 TB/sec or more.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been described in connection with some implementations, it should be understood that the disclosure is not limited to the disclosed implementations, but, on the contrary, is intended to cover various modifications and equivalent arrangements included within the spirit and scope of the appended claims.

What is claimed is:

1. An integrated circuit comprising:
a first layer that extends in a first direction; and
a second layer that is below the first layer, wherein the second layer extends in a second direction perpendicular to the first direction, the second layer is electrically connected to the first layer, and the second layer corresponds to a first signal pin of a first standard cell among a plurality of standard cells, and
wherein the first layer overlaps a first cell boundary among a plurality of cell boundaries of the plurality of standard cells in the first direction.

2. The integrated circuit of claim 1, comprising a third layer that is below the first layer, wherein the third layer extends in the second direction, the third layer is electrically connected to the first layer, and the third layer corresponds to a second signal pin of a second standard cell among the plurality of standard cells.

3. The integrated circuit of claim 2, wherein the second layer and the third layer are at the same layer.

4. The integrated circuit of claim 2, wherein the second layer is a contact layer of the first standard cell, and the third layer is a gate line of the second standard cell.

5. The integrated circuit of claim 1, comprising a fourth layer that is above the first layer, wherein the fourth layer extends in the second direction, and the fourth layer is electrically connected to the first layer.

6. The integrated circuit of claim 1, comprising a fifth layer that is at the same layer as the first layer, wherein the fifth layer extends in the first direction between two cell boundaries of the first standard cell, the two cell boundaries extend in the first direction, and the fifth layer is electrically connected to the second layer.

7. The integrated circuit of claim 6, comprising a sixth layer that is below the fifth layer, wherein the sixth layer extends in the second direction, the sixth layer is electrically connected to the fifth layer, and the sixth layer corresponds to a third signal pin of a third standard cell among the plurality of standard cells.

8. The integrated circuit of claim 7, wherein a fourth standard cell is between the first standard cell and the third standard cell in the first direction.

9. The integrated circuit of claim 6, wherein a width of the first layer is different from a width of the fifth layer.

10. The integrated circuit of claim 9, wherein the width of the first layer is greater than the width of the fifth layer.

11. The integrated circuit of claim 1, wherein the first layer has a first length in the first direction, the first length includes a first section and a second section, the first layer has a first width in the first section of the first length and a second width in the second section of the first length, and the second width is different from the first width.

12. The integrated circuit of claim 1, comprising a sixth layer that is below the second layer, wherein the sixth layer is configured to supply a power source voltage to the first standard cell through a second source/drain pattern, the second source/drain pattern is spaced apart from a first source/drain pattern in the first direction, and the first source/drain pattern is electrically connected to the second layer.

13. An integrated circuit comprising:
a first standard cell that includes a gate line and a first contact layer, the gate line corresponding to a first signal pin and extending in a first direction, the first contact layer corresponding to a second signal pin and extending in the first direction; and
a first layer that is electrically connected to the gate line or the first contact layer, wherein the first layer extends in a second direction perpendicular to the first direction at a layer above the gate line and the first contact layer.

14. The integrated circuit of claim 13, wherein the first layer overlaps a cell boundary of two cell boundaries of the first standard cell, and the two cell boundaries extend in the second direction.

15. The integrated circuit of claim 13, comprising:
a second standard cell that includes a second contact layer corresponding to a third pin and extending in the first direction; and
a second layer that is at the same layer as the first layer, wherein the second layer is electrically connected to the gate line or the first contact layer, the second layer is electrically connected to the second contact layer, and the second layer extends in the second direction.

16. The integrated circuit of claim 15, comprising a third standard cell that is between the first standard cell and the second standard cell in the second direction.

17. The integrated circuit of claim 15, wherein the two cell boundaries extend along the second direction and are located at different position from the second layer along the first direction.

18. The integrated circuit of claim 17, wherein the second layer is between the two cell boundaries of the first standard cell in the first direction.

19. An integrated circuit comprising:
a first layer that extends in a first direction, wherein the first layer is configured to supply a power source voltage;
a second layer that is spaced apart from the first layer along a second direction perpendicular to the first direction, wherein the second layer extends in the first direction, and the second layer is at the same layer as the first layer;
a first standard cell that includes a third layer corresponding to a first signal pin, wherein the first signal pin is configured to transmit a signal, the third layer is below the first layer, the third layer is electrically connected to the second layer, and the first standard cell is electrically connected to the first layer; and
a second standard cell that includes a fourth layer corresponding to a second signal pin, wherein the second signal pin is configured to receive the signal, the fourth layer is at the same layer as the third layer, and the fourth layer is electrically connected to the second layer.

20. The integrated circuit of claim 19, comprising a third standard cell that is between the first standard cell and the second standard cell in the first direction.
